(19) United States
(12) Patent Application Publication
(10) Pub. No.: US 2010/0216282 A1
(43) Pub. Date: Aug. 26, 2010

(54) LOW COST BONDING TECHNIQUE FOR INTEGRATED CIRCUIT CHIPS AND PDMS STRUCTURES

(75) Inventors: Hua Wang, Pasadena, CA (US); Seyed Ali Hajimiri, Pasadena, CA (US)

Correspondence Address: MILSTEIN ZHANG & WU LLC, 49 LEXINGTON STREET, SUITE 6, NEWTON, MA, 02465-1062, US

(73) Assignee: California Institute of Technology, Pasadena, CA (US)

(21) Appl. No.: 12/713,128

(22) Filed: Feb. 25, 2010

Related U.S. Application Data
(60) Provisional application No. 61/208,527, filed on Feb. 25, 2009.

(51) Int. Cl. H01L 21/60; H01L 21/50

(52) U.S. Cl. 438/118; 257/E21.499; 257/E21.506

(57) ABSTRACT

Methods of bonding a structure fabricated in polydimethylsiloxane (PDMS) and an integrated circuit chip. The procedures for bonding include providing a substrate, affixing the integrated circuit to the substrate, as needed preparing the surface of the integrated circuit chip to permit bonding, aligning the PDMS structure and the features of the integrated circuit chip, and applying a bonding agent. The bonding agent is cured by exposure to a thermal regime for a suitable length of time. Depending on relative sizes, in some cases, a plural number of PDMS structures can be attached to one chip, or a single PDMS structure can be bonded to multiple chips. In some cases, the integrated circuit chip operates wirelessly. In other situations, the substrate provides electrical communication from the integrated circuit chip to electronic components.

### CROSS-REFERENCE TO RELATED APPLICATIONS

This application claims priority to and the benefit of co-pending U.S. provisional patent application Ser. No. 61/208,527, filed Feb. 25, 2009, which application is incorporated herein by reference in its entirety. The following co-pending applications, all assigned to the assignee of this application, are related applications, and each is incorporated herein by reference in its entirety for all purposes: U.S. Ser. No. 12/399,320 filed Mar. 6, 2009; U.S. Ser. No. 12/399,603 filed Mar. 6, 2009; and U.S. Ser. No. 12/559,517 filed Sep. 15, 2009.

### STATEMENT REGARDING FEDERALLY FUNDED RESEARCH OR DEVELOPMENT

NOT APPLICABLE.

### THE NAMES OF THE PARTIES TO A JOINT RESEARCH AGREEMENT

NOT APPLICABLE.

### INCORPORATION-BY-REFERENCE OF MATERIAL SUBMITTED ON A COMPACT DISC

NOT APPLICABLE.

### FIELD OF THE INVENTION

The invention relates to assembling electromechanical devices in general and particularly to systems and methods for bonding polydimethylsiloxane (PDMS) structures in alignment with integrated circuit components, such as silicon integrated circuit (IC) chips.

### BACKGROUND OF THE INVENTION

Integrated circuit technology nowadays presents itself as a promising and powerful tool for biomedical and chemical applications. Integrated circuits are potentially viable to be used as sensors and actuators that are capable of generating and detecting electromagnetic (EM) signals with high accuracy and sensitivity. Moreover, some integrated circuit process, such as CMOS or SiGe can implement millions of transistors onchip, which provides unparallel signal processing power. Furthermore, some integrated circuit techniques are capable of generating high power, e.g. watt-level and beyond, which could serve as controllable electrical/magnetic stimulus. In addition, integrated circuits can augment traditional BioMEMS to achieve overall low system form-factor for implantable and ultraportable applications.

On the other hand, to form a complete sensing and/or actuation system, low cost polydimethylsiloxane (PDMS) devices are often used to provide specific functionality, such as for devices or systems for biomedical and/or chemical applications, including by way of example, sensing, actuating, and synthesizing. Such systems require micro/nano fabricated devices to provide functionality such as handling and manipulating samples in the liquid or the gaseous state. One of the most widely used micro/nano fabrication process is based on polydimethylsiloxane (PDMS) polymer material. PDMS is chemically inert, is biocompatible, and is non-flammable. Moreover, PDMS structures can be fabricated by soft lithography processes, which dramatically reduces the total fabrication cost. In addition, significant research efforts have been expended on developing complicated microfluidic structures using PDMS material, including by way of example fluidic channels, pumps, valves, mixers, cell sorters, and measuring apparatus.

However standard integrated circuits and PDMS devices conventionally are fabricated independently. An unmet need is the provision of reliable and low-cost methods to attach a fabricated PDMS structure or device onto an IC chip.

Existing techniques to achieve device-to-IC bonding have several apparent limitations. These techniques are not compatible with the aforementioned PDMS process, because they rely on other polymer materials, such as SU-8 and polyimide. Furthermore, the existing techniques require complicated post-processing steps, including patterning and etching. This significantly increase the total cost of the system.

There is a need to provide integrated circuit technology and integrated biomedical/chemical systems on a single substrate in a convenient and cost effective manner.

### SUMMARY OF THE INVENTION

According to one aspect, the invention relates to a method of bonding a polydimethylsiloxane (PDMS) structure and an integrated circuit chip. The method comprises the steps of: providing a substrate; mechanically attaching to the substrate at least one integrated circuit chip having an integrated circuit chip surface configured to have a PDMS structure bonded thereto; preparing the integrated circuit chip surface for bonding; aligning a PDMS structure with the at least one integrated circuit chip; applying an adhesive to the aligned PDMS structure and the at least one integrated circuit chip; and curing the adhesive.

In one embodiment, the substrate is selected from the group consisting of a printed circuit board (PCB), a brass board, a gold-plated brass board, and a board comprising a material selected from the group consisting of as-fired alumina, polished alumina, aluminum nitride, beryllium oxide, fused silica, quartz, sapphire, and polished titanate.

In one embodiment, the at least one integrated circuit chip is configured to interact with external electronic components by wireless communication.

In one embodiment, the substrate has at least one substrate electrical terminal configured to be connected to electronic components separate from the substrate and the integrated circuit chip has at least one electrical contact pad, the method further comprising the step of: electrically connecting the at least one substrate electrical terminal and the at least one electrical contact pad of the at least one integrated circuit chip. In one embodiment, the step of electrically connecting the at least one substrate electrical terminal and the at least one electrical contact pad of the at least one integrated circuit chip comprises electrically connecting using wire bonding. In one embodiment, the step of electrically connecting the at least one substrate electrical terminal and the at least one electrical contact pad of the at least one integrated circuit chip comprises electrically connecting using solder reflow.

In one embodiment, the step of preparing the integrated circuit chip surface for bonding comprises carefully cleaning an area of the integrated circuit chip surface that is to be bonded to the PDMS structure. In one embodiment, the step of preparing the integrated circuit chip surface for bonding comprises a cleaning method selected from the group of cleaning methods consisting of the use of a solvent, the use of supercritical carbon dioxide, the use of an organic fluid, the use of an inorganic fluid, the use of a gas, the use of a surfactant, and the use of ultrasonic cleaning.

In one embodiment, the step of applying an adhesive to the aligned PDMS structure and the at least one integrated circuit chip comprises applying an adhesive containing PDMS part A and PDMS part B. In one embodiment, a ratio of the PDMS part A and the PDMS part B is in the proportions of approximately 20 to 1 by weight.

In one embodiment, a plurality of PDMS structures are bonded to a single integrated circuit chip. In one embodiment, a single PDMS structure is bonded to a plurality of integrated circuit chips. In one embodiment, a number M of PDMS structures are bonded to a number N of integrated circuit chips, where M and N are each integers greater than one.

In one embodiment, the PDMS structure is a microfluidic device. In one embodiment, the PDMS structure is a microfluidic reaction chamber. In one embodiment, the PDMS structure is a microfluidic sensor cell.

In one embodiment, the integrated circuit chip is a silicon integrated circuit chip. In one embodiment, the integrated circuit chip comprises a selected one of a heater ring structure, a temperature sensor, a temperature reference, and a temperature to electrical signal amplifier, an integrated magnetic particle sensor, and a sensing/controlling circuit. In one embodiment, the integrated circuit chip comprises a material having a low PDMS affinity, and the step of preparing the integrated circuit chip surface for bonding comprises treating the integrated circuit chip surface to provide a surface having a high PDMS affinity.

In one embodiment, the substrate comprises a material having a low PDMS affinity, the method further comprising the step of: preparing the substrate surface to provide a surface having a high PDMS affinity.

In one embodiment, the curing step comprises applying a thermal treatment at a selected temperature for a suitable duration of time, the duration dependent on the temperature.

The foregoing and other objects, aspects, features, and advantages of the invention will become more apparent from the following description and from the claims.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views.

FIG. 1 is a flowchart showing the steps in an illustrative bonding process according to the principles of the invention.

FIG. 2 is a flowchart showing the steps of an alternative bonding process according to the principles of the invention.

FIG. 3 is a flowchart showing the steps of an alternative bonding process in which a wireless integrated circuit chip is employed, according to the principles of the invention.

FIG. 4 is a diagram showing an illustrative embodiment of the invention after the first step of FIG. 1.

FIG. 5 is a diagram showing an illustrative embodiment of the invention after the electrical bonding step of FIG. 1.

FIG. 6 is a schematic perspective view of the aligning step of attaching the PDMS structure onto the IC chip.

FIG. 7 is a schematic plan view of the aligning step of attaching the PDMS structure onto the IC chip.

FIG. 8 is a perspective view of the step of applying the mixture around the PDMS structure.

FIG. 9 is a plan view of the step of applying the mixture around the PDMS structure.

FIG. 10 is a diagram showing an example of a PDMS structure bonded to a silicon IC chip according to the principles of the invention.

FIG. 11 is an illustration showing a detailed view of PDMS structure illustrated in U.S. Ser. No. 12/399,603 as FIG. 20C.

FIG. 12 is a diagram showing the registration of features of the bonded PDMS structure in registry with circuit elements of the silicon IC chip illustrated in U.S. Ser. No. 12/559,517 as FIG. 20A.

FIG. 13 is a diagram showing in greater detail a portion of the registration of features of the bonded PDMS structure in registry with circuit elements of the silicon IC chip shown in FIG. 12.

### DETAILED DESCRIPTION

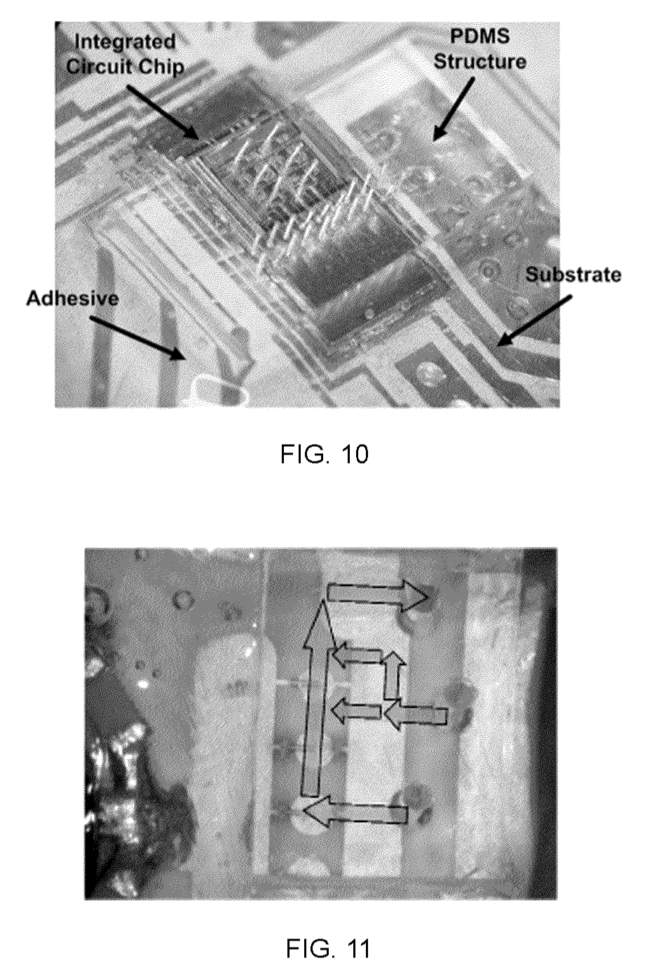

Reliable bonding between a PDMS device and an IC chips is an important step for system integration. To address these issues, we describe a novel bonding technique which is fully compatible with PDMS devices. This technique can be used for bonding any PDMS devices or micro/nano structures (such as MEMS devices) with PDMS as its bottom layer onto any integrated circuit chip with silicon dioxide or any other material as its upper-most passivation layer, as long as the passivation layer has a high affinity with PDMS. While the illustrative embodiments provided as examples are described with regard to silicon integrated circuit chips, it is to be understood that the methods described can be applied using any semiconductor chip, which will be referred to generally as an integrated circuit chip (e.g., a chip comprising a semiconductor other than silicon, such as SiGe, GaAs, or other III-V compounds and alloys thereof in which integrated circuits may be fabricated). An integrated circuit chip with a passivation layer having a low PDMS affinity can be first treated by a simple and low-cost process such as spin-on-glass coating or chemical vapor deposition (CVD) to coat a material having a high PDMS affinity as the upper-most passivation layer of the chip. The bonding can be accomplished using our technique. A substrate material may also have a low PDMS affinity, and can be treated to provide a high PDMS affinity. The treatment to can be mechanical as well as by adding a surface coating. A mechanical treatment, such as punching holes in the substrate to increase the effective contact area between the substrate and the adhesive, is shown in FIG. 10.

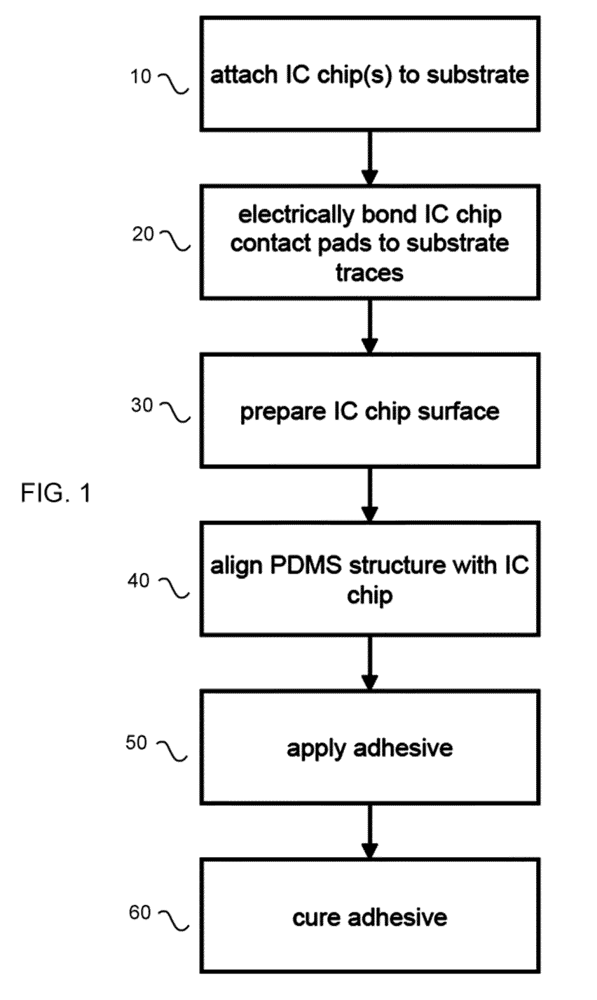

FIG. 1 is a flowchart showing the steps in an illustrative bonding process. In step 10, one or more IC chips are mechanically attached to a substrate, which can be, but is not limited to, a printed circuit board (PCB), a brass board, a gold-plated brass board, and a board comprising a material selected from the group consisting of as-fired alumina, polished alumina, aluminum nitride, beryllium oxide, fused silica, quartz, sapphire, and polished titanate, or some other supporting structure. Adhesive material, for example, silver epoxy, can be used to facilitate this mechanical attachment.

In step 20, the contact pads or terminals of the IC chip are electrically connected to the traces of the substrate. In some embodiments, wire bonds are used to connect the pads on the IC chip with the electrical conductive traces, as is shown in FIG. 5. In other embodiments, the IC chip can be assembled on the substrate by the commercially employed flip-chip technique, in which case steps 10 and 20 of FIG. 1 may be accomplished simultaneously in that the mechanical alignment of the IC chip to the substrate and the electrical connection of the IC chip and the substrate are performed in a single operation involving, for example, alignment and reflow soldering.

In FIG. 1, the step 30 of preparing the IC chip surface involves carefully cleaning the IC chip surface area that will be bonded to a PDMS structure. This can involve any convenient cleaning method, including the use of solvents such as supercritical carbon dioxide, use of organic fluids, use of inorganic fluids, use of gases, and the use of surfactants, as well as ultrasonic cleaning.

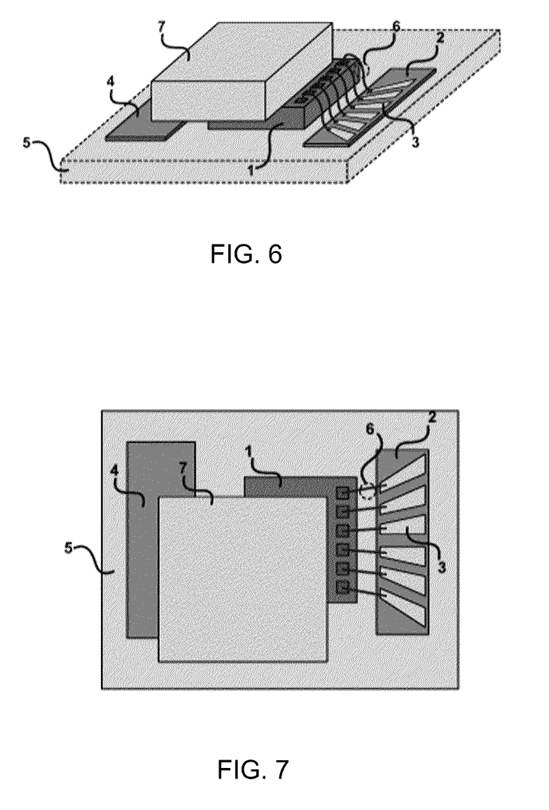

In FIG. 1, the step 40 of aligning the PDMS structure to be bonded to the IC chip is performed. FIG. 10 and FIG. 11 illustrate the alignment of elements or features within the PDMS structure with circuitry on the IC chip. In the alignment step 40, one places the PDMS structure or device onto the IC chip with selected features of one aligned with selected features of the other, as shown schematically in FIG. 6 and FIG. 7. In some embodiments, the PDMS structure is not necessarily smaller than the IC chip in its area. The PDMS structure or device can have a large area for integrating a plurality of features and functions. In some embodiments, multiple PDMS structures or devices can be placed onto multiple IC chips if necessary. The relative placement can be arranged so that N IC chips overlap with M PDMS devices, where N and M are independent integers and are each equal to or greater than one.

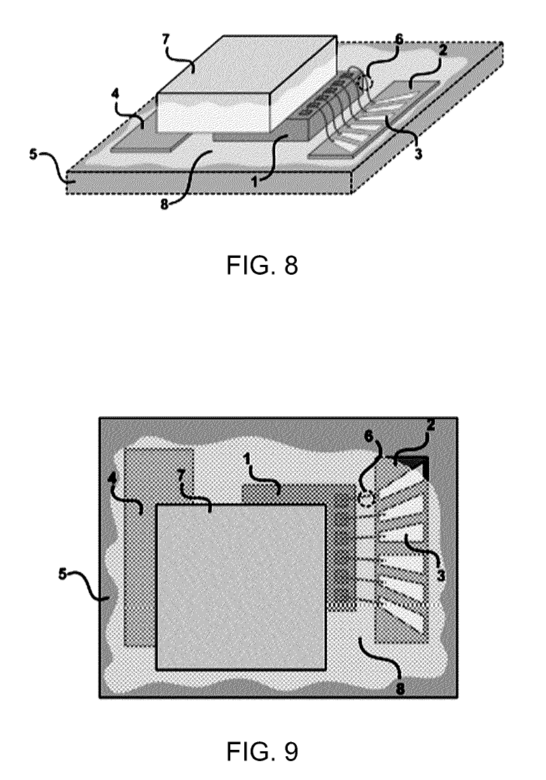

In FIG. 1, the step 50 of applying adhesive to the aligned PDMS structure and the IC chip is performed. In some embodiments, an adhesive comprising PDMS part A and PDMS part B (for example, GE Silicones RTV 615 kit, manufactured by Momentive Performance Materials (formerly GE Silicones), and available commercially from various vendors, including Applied Material Tech) is prepared by mixing part A:part B in the ratio of approximately 20:1 by weight, or in other appropriate weight ratios. Standard ratios of part A:part B according to the manufacturer are approximately 10:1. The mixture is applied as adhesive around the IC chip and the PDMS structures or devices, as is shown schematically in FIG. 8 and FIG. 9. If the wire bonds are present, they can be covered if necessary. The adhesive mixture can flow beneath the PDMS structure or device which is presented outside the footprint of the IC chip. In addition, the adhesive mixture can flow onto the substrate and/or the substrates which support the electrical conductive traces.

In FIG. 1, the step 60 of curing the adhesive mixture applied to the aligned PDMS structure and the IC chip is performed by any of the following thermal treatments. The aligned PDMS structure and the IC chip at can be maintained at around 70° C. for 30 minutes; at around 40° C. overnight (e.g., 12 to 16 hours); or maintained at room temperature (approximately 20° C.) for about 2 days. The actual curing temperature and time can be varied, as long as the applied mixture is cured. In general, a longer temperature is expected if a lower curing temperature is used.

In some embodiments the Step 20 (electrically bonding the IC chip and the substrate) may be performed after any of the Steps 40-60 (aligning the PDMS structure with the IC Chip through curing the adhesive). In some embodiments, it may be possible to attach the PDMS structure onto the IC chip first and then do the wire bonding.

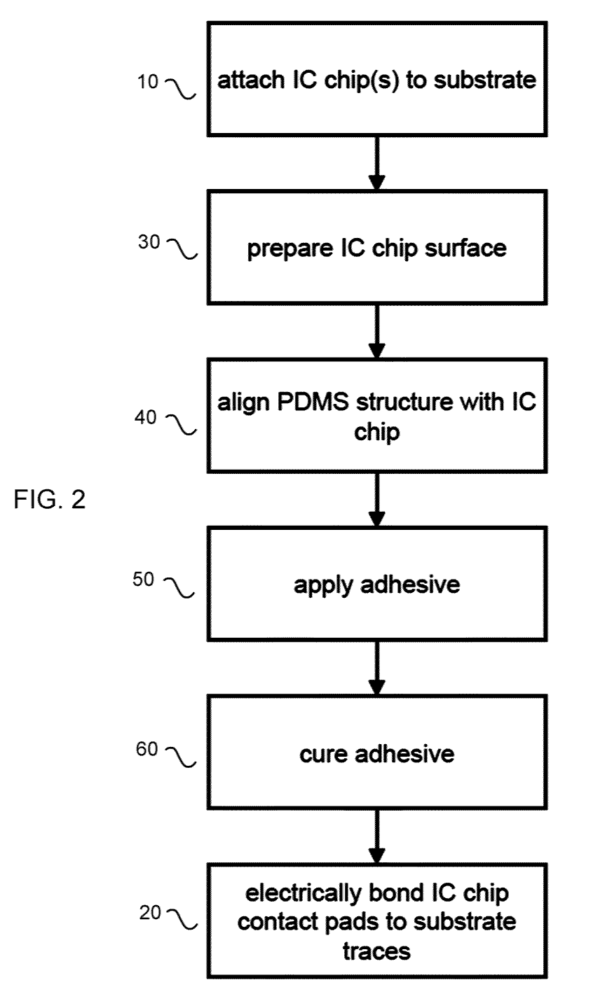

FIG. 2 is a flowchart showing the steps of an alternative bonding process. In FIG. 2, the various steps have the same meaning as the correspondingly numbered steps in FIG. 1, but the electrical connection step 20 is performed last.

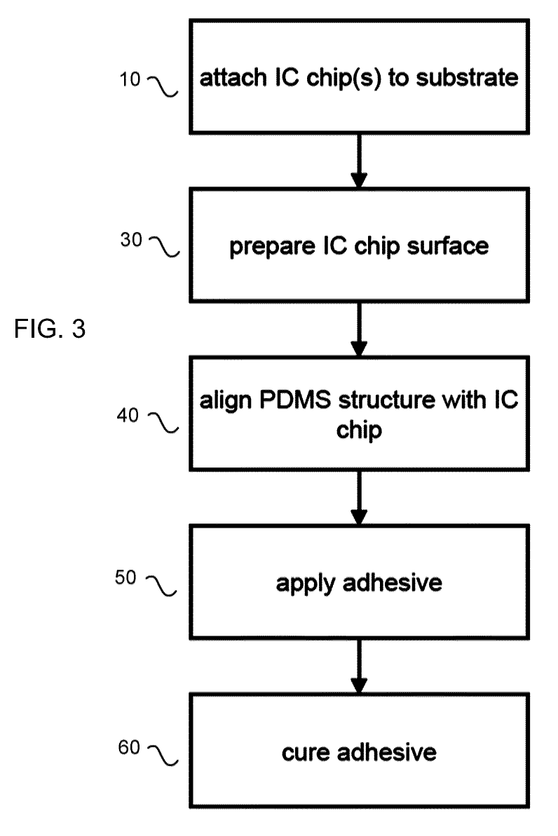

FIG. 3 is a flowchart showing the steps of an alternative bonding process in which a wireless integrated circuit chip is employed, according to the principles of the invention. The process described in FIG. 3 is similar to both the process of FIG. 1 and the process of FIG. 2, but does not require step 20 in which the contact pads or terminals of the IC chip are electrically connected to the traces of the substrate. Accordingly, step 20 has been omitted in the process of FIG. 3.

In the method illustrated in FIG. 3, the integrated circuit chip can, for example be an integrated circuit chip used to sense impedance for an incoming biological sample and the entire integrated circuit chip is powered by wireless energy which is inductively transferred from off-chip sources and regulated on chip. Communication of data or control signals to and from the integrated circuit chip can also be implemented wirelessly. In such an embodiment, one does not require any electrical connections between the integrated circuit chip with the substrate, and the substrate need not have any electrical terminals as well. The substrate can just provide a mechanical support for the integrated circuit chip.

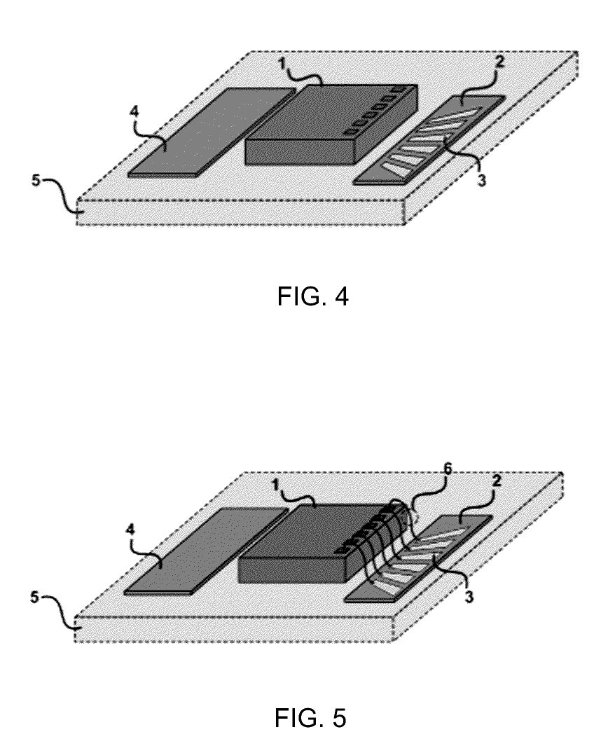

FIG. 4 is a diagram showing an illustrative embodiment of the invention after the first step of FIG. 1. In FIG. 4, substrate 5 supports an IC chip 1. Electrically conductive contacts or traces 3 are provided on a terminal block 2 of the substrate 5. In some embodiments, one or more additional terminal blocks 4 are provided if the substrate has to support additional electrically conductive contacts or traces.

FIG. 5 is a diagram showing an illustrative embodiment of the invention after the electrical bonding step of FIG. 1. In FIG. 5, wire bonds 6, for example using gold wires, are used to provide electrical connection between electrical traces 3 of the substrate 5 with the electrical pads of IC chip 1.

FIG. 6 is a schematic perspective view of the aligning step of attaching the PDMS structure onto the IC chip. In FIG. 6, the PDMS device 7 is aligned with the IC chip 1.

FIG. 7 is a schematic plan view of the aligning step of attaching the PDMS structure onto the IC chip.

FIG. 8 is a perspective view of the step 50 of applying the mixture 8 around the PDMS structure 7.

FIG. 9 is a plan view of the step 50 of applying the mixture 8 around the PDMS structure 7.

FIG. 10 is a diagram showing an example of a PDMS structure bonded to a silicon IC chip according to the principles of the invention.

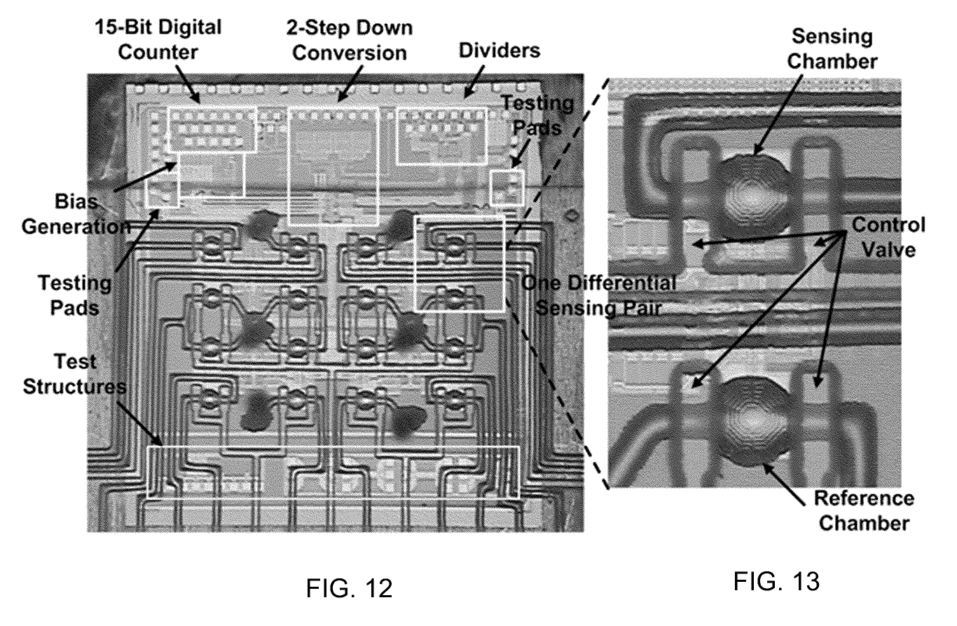

In order to provide additional examples of PDMS structures that may be bonded to silicon IC chips, the descriptions of the following patent applications, all assigned to the same assignee of the present application, are each incorporated herein by reference in their entirety for all purposes: U.S. Ser. No. 12/399,320 filed Mar. 6, 2009 that describes a PDMS-based microfluidic reaction chamber placed on top of a heater ring structure provided on a silicon wafer or a silicon-on-insulator (SOI) wafer having one or more control circuit array elements each comprising a temperature sensor, a temperature reference, and a temperature to electrical signal amplifier, along with the necessary power and control traces needed to operate each such control circuit; U.S. Ser. No. 12/399,603 filed Mar. 6, 2009 that describes a microfluidic channel together with pneumatic control valves fabricated in a polydimethylsiloxane (PDMS) material and operated in conjunction with an integrated magnetic particle sensor substrate such as a silicon CMOS chip to perform magnetic particle sensing, as shown in FIG. 11; U.S. Ser. No. 12/559,517 filed Sep. 15, 2009 that describes one or more PDMS-based microfluidic sensor cells can be placed on top of a CMOS temperature controller having a heater ring structure and a sensing/controlling circuit, as shown in FIG. 12 and FIG. 13.

Any patent, patent application, or publication identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. A method of bonding a polydimethylsiloxane (PDMS) structure and an integrated circuit chip, comprising the steps of:
providing a substrate;
mechanically attaching to said substrate at least one integrated circuit chip having an integrated circuit chip surface configured to have a PDMS structure bonded thereto;
preparing said integrated circuit chip surface for bonding;
aligning a PDMS structure with said at least one integrated circuit chip;
applying an adhesive to said aligned PDMS structure and said at least one integrated circuit chip; and
curing said adhesive.

2. The method of bonding a polydimethylsiloxane (PDMS) structure and an integrated circuit chip of claim 1, wherein said substrate is selected from the group consisting of a printed circuit board (PCB), a brass board, and a gold-plated brass board, and a board comprising a material selected from the group consisting of as-fired alumina board, polished alumina, aluminum nitride, beryllium oxide, fused silica, quartz, sapphire, and polished titanate.

3. The method of bonding a polydimethylsiloxane (PDMS) structure and an integrated circuit chip of claim 1, wherein said at least one integrated circuit chip is configured to interact with external electronic components by wireless communication.

4. The method of bonding a polydimethylsiloxane (PDMS) structure and an integrated circuit chip of claim 1, wherein said substrate has at least one substrate electrical terminal configured to be connected to electronic components separate from said substrate and said integrated circuit chip has at least one electrical contact pad, the method further comprising the step of:
electrically connecting said at least one substrate electrical terminal and said at least one electrical contact pad of said at least one integrated circuit chip.

5. The method of bonding a polydimethylsiloxane (PDMS) structure and an integrated circuit chip of claim 4, wherein said step of electrically connecting said at least one substrate electrical terminal and said at least one electrical contact pad of said at least one integrated circuit chip comprises electrically connecting using wire bonding.

6. The method of bonding a polydimethylsiloxane (PDMS) structure and an integrated circuit chip of claim 4, wherein said step of electrically connecting said at least one substrate electrical terminal and said at least one electrical contact pad of said at least one integrated circuit chip comprises electrically connecting using solder reflow.

7. The method of bonding a polydimethylsiloxane (PDMS) structure and an integrated circuit chip of claim 1, wherein said step of preparing said integrated circuit chip surface for bonding comprises carefully cleaning an area of the integrated circuit chip surface that is to be bonded to said PDMS structure.

8. The method of bonding a polydimethylsiloxane (PDMS) structure and an integrated circuit chip of claim 1, wherein said step of preparing said integrated circuit chip surface for bonding comprises a cleaning method selected from the group of cleaning methods consisting of the use of a solvent, the use of supercritical carbon dioxide, the use of an organic fluid, the use of an inorganic fluid, the use of a gas, the use of a surfactant, and the use of ultrasonic cleaning.

9. The method of bonding a polydimethylsiloxane (PDMS) structure and an integrated circuit chip of claim 1, wherein said step of applying an adhesive to said aligned PDMS structure and said at least one integrated circuit chip comprises applying an adhesive containing PDMS part A and PDMS part B.

10. The method of bonding a polydimethylsiloxane (PDMS) structure and an integrated circuit chip of claim 9, wherein a ratio of said PDMS part A and said PDMS part B is in the weight proportions of approximately 20 to 1.

11. The method of bonding a polydimethylsiloxane (PDMS) structure and an integrated circuit chip of claim 1, wherein a plurality of PDMS structures are bonded to a single integrated circuit chip.

12. The method of bonding a polydimethylsiloxane (PDMS) structure and an integrated circuit chip of claim 1, wherein a single PDMS structure is bonded to a plurality of integrated circuit chips.

13. The method of bonding a polydimethylsiloxane (PDMS) structure and an integrated circuit chip of claim 1, wherein a number M of PDMS structures are bonded to a number N of integrated circuit chips, where M and N are each integers greater than one.

14. The method of bonding a polydimethylsiloxane (PDMS) structure and an integrated circuit chip of claim 1, wherein said PDMS structure is a microfluidic device.

15. The method of bonding a polydimethylsiloxane (PDMS) structure and an integrated circuit chip of claim 1, wherein said PDMS structure is a microfluidic reaction chamber.

16. The method of bonding a polydimethylsiloxane (PDMS) structure and an integrated circuit chip of claim 1, wherein said PDMS structure is a microfluidic sensor cell.

17. The method of bonding a polydimethylsiloxane (PDMS) structure and an integrated circuit chip of claim 1, wherein said integrated circuit chip is a silicon integrated circuit chip.

18. The method of bonding a polydimethylsiloxane (PDMS) structure and an integrated circuit chip of claim 1, wherein said integrated circuit chip comprises a selected one of a heater ring structure, a temperature sensor, a temperature reference, and a temperature to electrical signal amplifier, an integrated magnetic particle sensor, and a sensing/controlling circuit.

19. The method of bonding a polydimethylsiloxane (PDMS) structure and an integrated circuit chip of claim 1, wherein said integrated circuit chip comprises a material having a low PDMS affinity, and said step of preparing said integrated circuit chip surface for bonding comprises treating said integrated circuit chip surface to provide a surface having a high PDMS affinity.

20. The method of bonding a polydimethylsiloxane (PDMS) structure and an integrated circuit chip of claim 1, wherein said substrate comprises a material having a low PDMS affinity, the method further comprising the step of:
preparing said substrate surface to provide a surface having a high PDMS affinity.

21. The method of bonding a polydimethylsiloxane (PDMS) structure and an integrated circuit chip of claim 1, wherein said curing step comprises applying a thermal treatment at a selected temperature for a suitable duration of time, said duration dependent on said temperature.
